(19) United States
(12) Patent Application Publication
(10) Pub. No.: US 2013/0216777 A1
(43) Pub. Date: Aug. 22, 2013

(54) Nanostructured Multi-Layer Coating on Carbides

(71) Applicants: Wenping Jiang, Fayetteville, AR (US); Mike Kimmel, Rogers, AR (US); Ajay P. Malshe, Springdale, AR (US)

(72) Inventors: Wenping Jiang, Fayetteville, AR (US); Mike Kimmel, Rogers, AR (US); Ajay P. Malshe, Springdale, AR (US)

(21) Appl. No.: 13/450,787

(22) Filed: Apr. 19, 2012

Related U.S. Application Data
(60) Provisional application No. 61/601,081, filed on Feb. 21, 2012.

(51) Int. Cl. B24D 3/00; C23C 16/455; B32B 9/04; B82Y 40/00; B82Y 30/00

(52) U.S. Cl. 428/141; 427/255.28; 428/698; 428/336; 977/773; 977/902

(57) ABSTRACT

A coating for carbide substrates to produce cutting tool inserts employs a lower nanostructured layer in conjunction with a non-nanostructured layer. The nanostructured layer is produced by the addition of a refining agent flow, particular hydrogen chloride gas, during deposition. The combination of a nanostructured layer and non-nanostructured layer of coatings is believed to produce a cutting tool insert that exhibits longer life, particularly in conjunction with particularly difficult cutting applications such as the cutting of hardened steel with severe interruptions.

### CROSS-REFERENCE TO RELATED APPLICATIONS

This application claims priority from U.S. provisional patent application No. 61/601,081, filed Feb. 21, 2012, and entitled “Nanostructured Multi-Layer Coating on Carbides.”

### STATEMENT REGARDING FEDERALLY SPONSORED RESEARCH OR DEVELOPMENT

Not applicable.

### BACKGROUND OF THE INVENTION

Coatings are effective for improving the performance of various materials, such as for achieving better wear resistance and corrosion resistance. Common applications where a coating is applied to a substrate to improve wear resistance of the substrate material include cutting tool inserts for the cutting of hard materials, such as hardened steel with interruptions. Common substrate materials for cutting tools may include, for example, hard metals of different particle sizes with a varied percentage of cobalt or nickel as a binder material.

Wear on the coatings of cutting tool inserts is a well-recognized problem, particular in connection with certain difficult cutting applications, such as the cutting of hard metals with severe interruptions. Coatings applied to carbide substrates produced using chemical vapor deposition (CVD) processes, a common technique, may be chipped off, resulting in premature failure of the cutting tool insert, or exhibit excessive flank wear, again leading to poor performance for the cutting tool insert. Multiple-layer coatings have been developed for cutting tool inserts as attempts to solve this problem. In particular, cutting tool inserts with multiple very thin coating layers have been developed. U.S. Pat. No. 6,103,357 to Selinder et al. teaches a cutting tool with multiple individual layers of aperiodic thickness over a substrate, where the thickness for each layer is greater than 0.1 nanometer but smaller than 30 nm, preferably smaller than 20 nm. It has been asserted that such tool inserts show markedly improved service life compared to comparable tool inserts with single-layer coatings having the same total thickness. Nevertheless, improved performance is still desired in order to increase the wear life of cutting tool inserts, particular those used with particularly difficult applications, such as the cutting of hardened steel with interruptions.

### BRIEF SUMMARY OF THE INVENTION

The present invention is directed to a multi-layer coating on a substrate comprising a nanostructured interfacial layer in conjunction with a non-nanostructured layer and optional additional layers. The result is improved hardness and toughness of the overall coating to reduce edge chip-off and flank wear, particularly in difficult applications such as machining hardened steel with interruptions.

In a first aspect, the invention is directed to a cutting tool insert, comprising a substrate, a first nanostructured coating deposited over the substrate, and a non-nanostructured coating layer deposited over the substrate.

In a second aspect, the invention is directed to a method for producing a coated substrate in a reactor, surprisingly using high-temperature chemical vapor deposition (CVD) techniques rather than traditional low-temperature physical vapor deposition (PVD) techniques, comprising the steps of depositing a first material on the substrate in a layer in conjunction with the release of a refining agent flow to produce a first nanostructured layer and optionally one or more additional nanostructured layers, and depositing a second material on the substrate to produce a non-nanostructured layer over the substrate.

These and other features, objects and advantages of the present invention will become better understood from a consideration of the following detailed description of the preferred embodiments and appended claims in conjunction with the drawings as described following:

### BRIEF DESCRIPTION OF THE SEVERAL VIEWS OF THE DRAWINGS

FIG. 1 is an illustration of a substrate with multiple coatings according to a preferred embodiment of the present invention.

FIG. 2 is an SEM photograph at a side elevational view of a cross-section of multiple coatings according to a preferred embodiment of the present invention.

FIG. 3A is an SEM photograph top planar view of a cross-section of a nanostructured TiN layer according to a preferred embodiment of the present invention.

FIG. 3B is an SEM photograph top planar view of a cross-section of a nanostructured TiCN layer according to a preferred embodiment of the present invention.

FIG. 4 is an SEM photograph side elevational view of a cross-section of a nanostructured layer according to a preferred embodiment of the present invention.

### DETAILED DESCRIPTION OF THE PREFERRED EMBODIMENT(S)

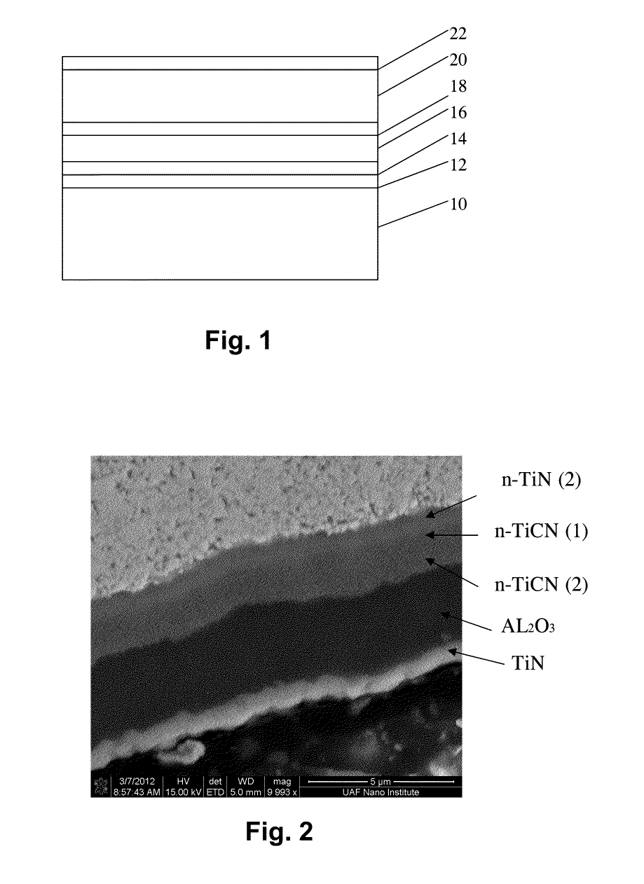

With reference to FIG. 1, a preferred embodiment of the present invention for use in connection with a cutting tool insert may be described. A substrate 10 forms a base for the tool insert. In the preferred embodiment, substrate 10 is formed of cemented carbide or hard metals, with tungsten carbide grain size in the sub-micron and micron range, and substrate 10 comprising about 5.0 to 15.0% of cobalt or nickel as a binder. The substrate of the preferred embodiment has a radius hone in the range of about 0.0005″ to 0.002″, the radius hone preferably being matched to the overall coating thickness.

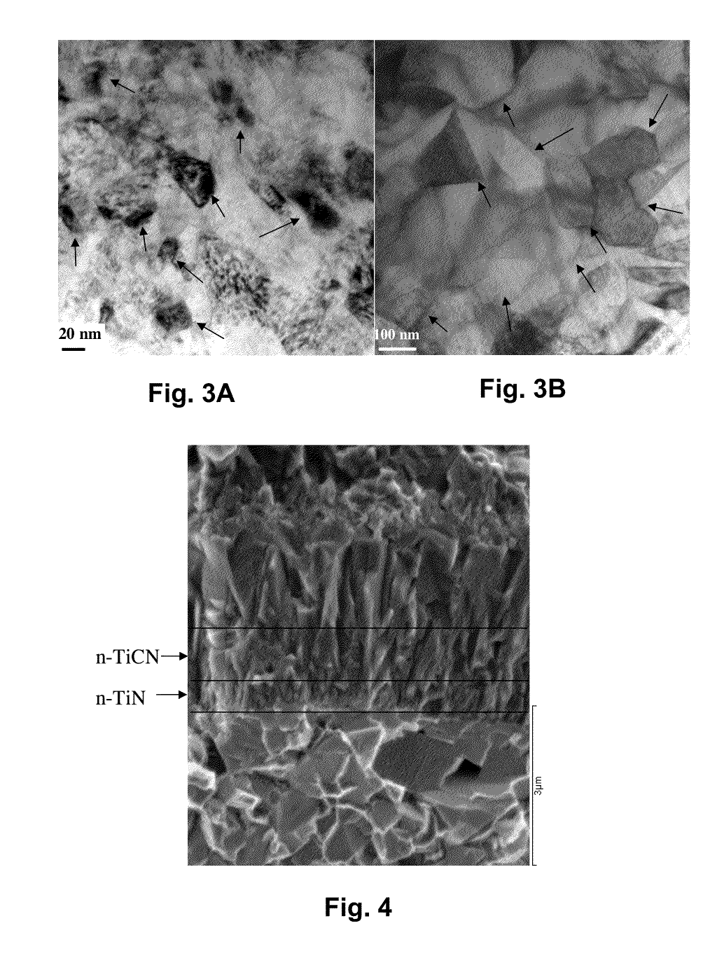

Layer 12 is a nanostructured layer of titanium nitride (TiN) with a thickness in the range of about 0.5 to 1.0 microns, with average grain size (measured on a plane perpendicular to the coating thickness) that is less than about 100 nm. For purposes herein, “nanostructured” may be defined as meeting at least one of three different tests: a coating of stacked layers having nanometric thickness (i.e., a thickness of no greater than about 100 nm); a coating layer containing nanoparticles (i.e., particles of a size no greater than about 100 nm); or a coating layer with nanosized grains in the X-Y plane (that is, parallel to the plane in which coatings are applied), even when the grains might have a diameter in the perpendicular direction that is not within the nanosize range, that is, greater than 100 nm. It may be noted that the layer's grain size for a nanostructured layer is not limited to this size (less than 100 nm) when measured on a plane parallel to the coating thickness, and the result may thus be “long” columnar grains that extend vertically in the direction of the coating thickness. FIG. 4 is an SEM photograph, taken in a direction parallel to the coating thickness, providing an example of this type of structure. FIG. 3A is a TEM image, taken in a direction perpendicular to the coating thickness, showing a TiN layer according to the preferred embodiment, where the individual nano-sized grains are visible in the nanostructure. It is believed that TiN layer 12 at this thickness provides a good interfacial layer because of its affinity for the material of substrate 10. While the preferred embodiment involves a non-composite layer 12 composed of only TiN, alternative embodiments may include a composite of different materials, in some cases including TiN in the composite, in layer 12.

Layer 14 is a nanostructured layer of titanium carbonitride (TiCN) with a thickness in the range of about 0.5 to 1.0 microns. This layer has a grain size (measured on a plane perpendicular to the coating thickness) of less than about 100 nm. As with layer 12, it may be noted that the layer's grain size is not limited to nanoscale size when measured on a plane parallel to the coating thickness, and the result may thus be “long” grains that extend vertically in the direction of the coating thickness. FIG. 3B is a TEM image, taken in a direction perpendicular to the coating thickness, showing a TiCN layer according to the preferred embodiment, where the individual nano-sized grains are visible in the nanostructure. It is believed that thin TiCN layer 14 provides desirable properties because it provides a grain-size match to the material of layer 12, thereby providing a minimum of stress at the point of the connection between these two layers, and providing a good transition to the next outer layer.

Layer 16 is a second nanostructured layer of TiCN, with a thickness of about 2.0 to 3.0 microns. Again, it may be noted that the layer's grain size is not limited to nanoscale size when measured on a plane parallel to the coating thickness, and the result may thus be “long” grains that extend vertically in the direction of the coating thickness.

Layer 18 is a layer of carbon-enriched TiCN with a thickness of about 0.1 to 0.6 microns. Layer 20 is a layer of aluminum oxide (Al₂O₃), with a thickness of about 3.0 to 4.0 microns. This material is desirable as a thermal barrier to the substrate and lower coating layers on the insert. Finally, layer 22 is an optional capping layer of TiN, with a thickness of less than about 2.0 microns.

The overall thickness of these six coatings, taken together, is about 8.0 to 10.0 microns. FIG. 2 is an SEM photograph in cross-section showing an example of these layers, with the breaks between material layers clearly visible. The ordering of layers is reversed from FIG. 1. It should be noted that although FIG. 1 does not depict this aspect of the preferred embodiment for the sake of clarity, the coating layers in commercial embodiments should preferably extend over the edges of substrate 10.

With respect to the preferred embodiment, grain size for the nanostructured layers as described above was performed using transmission electron microscopy (TEM) analysis, as is well understood in the art. Very thin samples (about 0.2 microns in thickness) were prepared with focused ion beam (FIB) methods. As may be seen in FIGS. 3A and 3B, average grain size is less than 100 nm for the nanostructured TiN and TiCN layers; the bar in the figures represents 50 nm. Again, the grain size was measured in the plane perpendicular to coating thickness, and thus the grain size in the plane parallel to coating thickness may be longer, as illustrated, for example, in FIG. 4, where the bar at the right of the figure represents 3 microns.

The structure of a preferred embodiment of the present invention having now been presented, the preferred method for producing this structure may now be described. Nanostructured TiN layer 12 is deposited using chemical vapor deposition (CVD) techniques using a grain-refining agent. In particular, the refining agent in the preferred embodiment is hydrogen chloride gas (HCl). The process is performed at a medium reactor temperature, specifically about 850° C. to about 920° C. in the preferred embodiment. It should be noted that HCl is generally seen as undesirable in CVD processes, since it tends to etch away or pit material that is being deposited, and thus slows the process of deposition. By slowing the process, it increases the cost of producing coated tool inserts. It has been found by the inventors, however, that HCl may be used to selectively etch or pit the layer as the deposition process moves forward in order to create nanostructured material. It is believed that the etching or pitting results in nucleation sites, that function to build nanostructure as the layer is deposited. The result, therefore, is a nanostructured layer of material that is produced at a relatively high rate of speed compared to what would be required to produce a similar layer without the refining agent. At this medium-temperature level, the grains produced are columnar, and thus within the definition of nanostructured as presented above.

Nanostructured TiCN layer 14 is also deposited using CVD techniques using the addition of HCl to produce a nanostructured layer. A medium-temperature process is employed, with a reactor temperature in this case of about 885° C. and reactor pressure of about 60 mbar. The second nanostructured TiCN layer 16 is applied at the same temperature, and again with added HCl, at a pressure of about 90 mbar. The TiCN with carbon enrichment layer 18 is deposited using a regular CVD process (no HCl added), at a higher temperature of about 1010° C. and reactor pressure of about 100 mbar.

Al₂O₃ layer 20 is deposited at a temperature of about 1005° to 1015° C. It may be noted that while certain references, such as U.S. Patent Publication No. 2006/0204757 to Ljungberg, teach that the Al₂O₃ layer desirably may be smoothed or fine-grained, it has been found by the inventors hereof that contrary to this teaching, roughness on this layer is not a detriment to the performance of the insert. For this reason, the inventors have been able to dramatically speed up the deposition process for this material as compared to prior art techniques, since slower deposition is required if a smooth finish is desired. In particular, the method of the preferred embodiment involves a deposition time for this Al₂O₃ layer of about 210 minutes, compared to a typical time of deposition of a comparably sized Al₂O₃ layer in prior art techniques (where a smooth surface is achieved) of about 4 hours. The TiN capping layer 22 is then deposited on top in a conventional CVD process.

The table below provides a summary of process parameters and precursors for each of the layers deposited on substrate 10.

| | | | | | | | | | Temp | Pressure | Duration |
|---|---|---|---|---|---|---|---|---|---|---|---|
| Coating | H₂ | N₂ | HCl | TiCl₄ | CH₃CN | CH₄ | CO₂ | H₂S | (° C.) | (mbar) | (min) |
| n-TiN | 53.4% | 34.3% | 4.67% | 7.63% | | | | | 930 | 160 | 60 |
| n-TiCN | 54.5% | 31.1% | 4.67% | 9.34% | balanced | | | | 885 | 60 | 60 |
| n-TiCN | 54.5% | 31.1% | 4.67% | 9.34% | balanced | | | | 885 | 90 | 180 |
| TiCN | 82.87% | 5.53% | | balanced | | 3.31% | | | 1010 | 100 | 30 |
| with | | | | | | | | | | | |
| carbon | | | | | | | | | | | |
| enriched | | | | | | | | | | | |
| layer | | | | | | | | | | | |
| Al₂O₃ | 87.46% | | 8.81% | | | | 3.4% | balanced | 1015 | 60 | 210 |
| TiN | 63.16% | 26.31% | | balanced | | | | | 1015 | 100 | 30 |

The insert may be finished for cutting by the use of edge preparation techniques as known in the art, including grinding, wire brushing, or similar processes.

With respect to the preferred embodiment as herein described, cutting tests were performed in connection with a target material of AISI 4340 hardened steel with severe interruptions. The inserts used for testing were CNMA432 carbide turning inserts, coated as described above. A benchmark test was performed using the same type of insert (same style and grade) coated with conventional coating techniques with similar chemistry but micron-sized grains in each of the coating layers. The workpiece used was a material with a diameter of 6.0″, with four deep, V-shaped slots in the peripherals to provide interruptions for testing, along with four ⅜″ diameter through-holes evenly distributed on the end surface. Machining conditions were as follows:
Surface speed: 400 SFM
Feed rate: 0.0004 IPR
Depth of cut: 0.01″
Dry/wet: with cutting fluid
Failure criteria: 0.008″ flank wear or 0.004″ crater wear

With these test parameters and workpiece specifications as set out above, the benchmark insert demonstrated a tool life before failure, on average, of about 7 minutes. The insert prepared according to the preferred embodiment of the present invention, as previously described, produced an average tool life before failure of about 20 minutes. It may be seen therefore that the invention produced markedly improved performance over prior art coating techniques for cutting tool inserts, particularly when used in connection with the cutting of hardened steel with severe interruptions, which is known in the art as a particularly difficult material with respect to cutting tool insert life. The preferred embodiment may also find particular application where impact resistance is desired in a cutting tool insert.

The inventors believe that the combination of nanostructured layers with other layers that are not nanostructured may be responsible for the dramatically improved performance of the preferred embodiment. The matching of nanostructured and non-nanostructured materials may produce a unique combinatorial architecture delivering dramatically improved results, achieving a cutting tool insert that is less prone to chip-off failure and flank wear problems. The transition from inner layers to outer layers of smaller-scaled to larger-scaled particles may create a better bond between the layers of the coating and between the coating and the substrate. This structure may also result in fewer stress points—or may compensate for stress points that result from material discontinuities/defects—within the structure of the substrate/coating matrix. The presence of stress points within the coating structure are believed by the inventors hereof to correlate with premature wear or failure.

As used herein, “comprising” is synonymous with “including,” “containing,” or “characterized by,” and is inclusive or open-ended and does not exclude additional, unrecited elements or method steps. As used herein, “consisting of” excludes any element, step, or ingredients not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

When a Markush group or other grouping is used herein, all individual members of the group and all combinations and subcombinations possible of the group are intended to be individually included in the disclosure.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims. Thus, additional embodiments are within the scope of the invention and within the following claims.

In general the terms and phrases used herein have their art-recognized meaning, which can be found by reference to standard texts, journal references and contexts known to those skilled in the art. The preceding definitions are provided to clarify their specific use in the context of the invention.

All patents and publications mentioned in the specification are indicative of the levels of skill of those skilled in the art to which the invention pertains. All references cited herein are hereby incorporated by reference to the extent that there is no inconsistency with the disclosure of this specification.

The present invention has been described with reference to certain preferred and alternative embodiments that are intended to be exemplary only and not limiting to the full scope of the present invention as set forth in the appended claims.

1. A cutting tool insert, comprising:
a. a substrate;
b. a first nanostructured coating deposited over the substrate, wherein the first nanostructured coating comprises at least one of (i) a thickness of no greater than 100 nm or (ii) grains having a dimension no greater than 100 nm as measured in a plane parallel to the substrate; and
c. a non-nanostructured coating deposited over the first nanostructured coating wherein the non-nanostructured coating comprises particles of size greater than 100 nm as measured in the plane parallel to the substrate to form a nanostructured-to-non-nanostructured interface at a bottom face of the non-nanostructured coating.

2. The cutting tool of claim 1, wherein the first nanostructured coating comprises titanium nitride.

3. The cutting tool of claim 2, wherein the first nanostructured coating is 0.5 to 1.5 microns in thickness.

4. The cutting tool of claim 1, further comprising a second nanostructured coating over the first nanostructured coating, wherein the second nanostructured coating comprises at least one of (i) a thickness of no greater than 100 nm or (ii) grains having a dimension no greater than 100 nm as measured in the plane parallel to the substrate.

5. The cutting tool of claim 4, wherein the second nanostructured coating comprises titanium carbonitride.

6. The cutting tool of claim 5, wherein the second nanostructured coating is 0.5 to 1.5 microns in thickness.

7. The cutting tool of claim 4, further comprising a third nanostructured coating over the second nanostructured coating, wherein the third nanostructured coating comprises at least one of (i) a thickness of no greater than 100 nm or (ii) grains having a dimension no greater than 100 nm as measured in the plane parallel to the substrate.

8. The cutting tool of claim 7, wherein the third nanostructured coating comprises titanium carbonitride.

9. The cutting tool of claim 8, wherein the third nanostructured coating is 2.0 to 4.0 microns in thickness.

10. The cutting tool of claim 1, wherein the non-nanostructured coating comprises carbon-enriched carbonitride.

11. The cutting tool of claim 10, wherein the non-nanostructured coating is 0.1 to 0.6 microns in thickness.

12. The cutting tool of claim 1, further comprising a thermal barrier coating.

13. The cutting tool of claim 12, wherein the thermal barrier coating is 2.0 to 4.0 microns thick.

14. The cutting tool of claim 13, wherein the thermal barrier coating comprises a rough surface.

15. The cutting tool of claim 12, further comprising a capping layer.

16. The cutting tool of claim 15, wherein the capping layer comprises titanium nitride.

17. The cutting tool of claim 16, wherein the capping layer is less than 2.0 microns in thickness.

18. The cutting tool of claim 1, wherein a total thickness of all coating layers on the substrate is 5.0 to 12.0 microns.

19. A method for producing a coated substrate for use as a cutting tool insert in a reactor using chemical vapor deposition (CVD) techniques, comprising:
a. depositing a first material on the substrate in a layer in conjunction with the release of a refining agent flow to produce a first nanostructured layer, wherein the first nanostructured coating comprises at least one of (i) a thickness of no greater than 100 nm or (ii) grains having a dimension no greater than 100 nm as measured in a plane parallel to the substrate; and
b. depositing a second material on the substrate to produce a non-nanostructured layer wherein the non-nanostructured coating comprises particles of size greater than 100 nm as measured in the plane parallel to the substrate to form a nanostructured-to-non-nanostructured interface at a face of the non-nanostructured layer.

20. The method of claim 19, wherein the refining agent is hydrogen chloride gas.

21. The method of claim 20, wherein the depositing a first material step is performed at a temperature in a range of 850° C. to 925° C.

22. The method of claim 21, wherein the depositing a first material step is performed in no more than 210 minutes.

23. The method of claim 19, comprising the additional step of depositing a third material on the substrate in conjunction with the release of a refining agent to produce a second nanostructured layer, wherein the second nanostructured coating comprises at least one of (i) a thickness of no greater than 100 nm or (ii) grains having a dimension no greater than 100 nm as measured in the plane parallel to the substrate.

24. The method of claim 23, wherein the depositing a third material step is performed at a temperature of 850° C. to 900° C.

25. The method of claim 23, comprising the additional step of depositing a fourth material on the substrate in conjunction with the release of a refining agent to produce a third nanostructured layer, wherein the third nanostructured coating comprises at least one of (i) a thickness of no greater than 100 nm or (ii) grains having a dimension no greater than 100 nm as measured in the plane parallel to the substrate.

26. The method of claim 25, wherein the depositing a fourth material step is performed at a temperature of 850° C. to 900° C.

27. The method of claim 19, wherein the depositing a non-nanostructured layer is performed at a temperature of about 1010° C.

28. The method of claim 26, further comprising the step of depositing a fifth material on the substrate to produce a thermal layer over the non-nanostructured layer.

29. The method of claim 28, wherein the step of depositing a thermal layer is performed in no more than 210 minutes.

30. The method of claim 28, further comprising the step of depositing a sixth material on the substrate to produce a capping layer over the thermal layer.
